(19) United States
(12) Patent Application Publication
(10) Pub. No.: US 2026/0101705 A1
(43) Pub. Date: Apr. 9, 2026

(54) SUBSTRATE PROCESSING CONGESTION MANAGEMENT APPARATUS AND SEMICONDUCTOR PROCESSING SYSTEM INCLUDING THE SAME

(71) Applicant: Samsung Electronics Co., Ltd., Suwon-si (KR)

(72) Inventors: Sonmook OH, Suwon-si (KR); Junmin LEE, Suwon-si (KR); Guihan KO, Suwon-si (KR); Jaeho JANG, Suwon-si (KR); Yohwan JOO, Suwon-si (KR)

(73) Assignee: Samsung Electronics Co., Ltd., Suwon-si (KR)

(21) Appl. No.: 19/059,858

(22) Filed: Feb. 21, 2025

(30) Foreign Application Priority Data
Oct. 8, 2024 (KR) 10-2024-0136821

(51) Int. Cl. H01L 21/67; G05B 19/418

(52) U.S. Cl. CPC H10P 72/0612; G05B 19/41865; G05B 2219/34418

(57) ABSTRACT

A substrate processing congestion management apparatus includes at least one processor configured to divide a process sequence of a substrate processing apparatus into specific sections and determine whether congestion occurs in the specific sections, to set an initial suspected region corresponding to a section in which the congestion occurs, analyze outliers in events occurring in the initial suspected region, deduce a final suspected region while updating the initial suspected region based on an event in which an outlier is identified, and determine, among the events, an event with a greatest contribution to the final suspected region as a congestion cause, and to notify the congestion cause and automatically control the substrate processing apparatus to reduce process congestion and improve substrate processing throughput, based on the determined congestion cause.

### CROSS-REFERENCE TO RELATED APPLICATION

This application is based on and claims priority under 35 U.S.C. § 119 to Korean Patent Application No. 10-2024-0136821, filed on Oct. 8, 2024, in the Korean Intellectual Property Office, the disclosure of which is incorporated by reference herein in its entirety.

### BACKGROUND

The inventive concept relates to a substrate processing congestion management apparatus and a substrate processing system including the same.

The semiconductor industry is a cutting-edge field requiring nanometer-level precision and high production efficiency. Substrate processing, which is the core of the semiconductor industry, includes complex and sequential operations to form integrated circuits on wafers. The smooth execution of the processing may directly impact the productivity and yield of the entire semiconductor manufacturing line.

Recently, as rapid advancements in semiconductor technology have led to increased chip integration and process miniaturization, the complexity of the substrate processing has significantly increased. Accordingly, the importance of process management has been increasingly highlighted, and specifically, the optimization of the process flow is emerging as a primary concern.

According to the nature of semiconductor manufacturing processes, the continuity and stability of the process flow are crucial. When congestion occurs, it is essential to quickly identify causes of congestion and respond promptly, which may directly impact productivity and yield. Therefore, there is an increasing need for automated congestion analysis systems for reducing manpower dependence and shortening analysis time.

### SUMMARY

The inventive concept provides a substrate processing congestion management apparatus capable of identifying causes of congestion occurring during substrate processing, and a substrate processing system including the substrate processing congestion management apparatus.

Technical problems to be solved by the inventive concept are not limited to the above description, and other technical problems may be clearly understood by one of ordinary skill in the art from the descriptions provided hereinafter.

According to an aspect of the inventive concept, a substrate processing congestion management apparatus may include at least one processor configured to divide a process sequence of a substrate processing apparatus into specific sections and determine whether congestion occurs in the specific sections, to set an initial suspected region corresponding to a section in which the congestion occurs, analyze outliers in events occurring in the initial suspected region, deduce a final suspected region while updating the initial suspected region based on an event in which an outlier is identified, and determine, among the events, an event with a greatest contribution to the final suspected region as a congestion cause, and to notify the congestion cause and automatically control the substrate processing apparatus to reduce process congestion and improve substrate processing throughput, based on the determined congestion cause by performing at least one of: adjusting gas flow parameters of at least one process chamber in the substrate processing apparatus; modifying radio frequency (RF) power delivery timing in the at least one process chamber; controlling pressure ramping rates between process steps performed by the substrate processing apparatus; updating transfer robot scheduling between adjacent process chambers of the at least one process chamber; or modifying maintenance timing of components in the at least one process chamber.

According to another aspect of the inventive concept, a substrate processing congestion management apparatus may include at least one processor configured to receive data associated with a process sequence of a substrate processing apparatus, to preprocess the received data, to divide the process sequence of the substrate processing apparatus into specific sections and determine whether congestion occurs in the specific sections, to set an initial suspected region corresponding to a section in which congestion occurs, analyze outliers in events occurring in the initial suspected region, deduce a final suspected region while updating the initial suspected region based on an event in which an outlier is identified, and determine, among the events, an event with a greatest contribution to the final suspected region as a congestion cause, to notify the congestion cause and automatically control the substrate processing apparatus to reduce process congestion and improve substrate processing throughput, based on the determined congestion cause by performing at least one of: adjusting gas flow parameters of at least one process chamber in the substrate processing apparatus; modifying radio frequency (RF) power delivery timing in the at least one process chamber; controlling pressure ramping rates between process steps performed by the substrate processing apparatus; updating transfer robot scheduling between adjacent process chambers of the at least one process chamber; or modifying maintenance timing of components in the at least one process chamber. A suspected region includes a section that contributes to the congestion cause, and each of the events includes an action performed for processes by the substrate processing apparatus.

According to still another aspect of the inventive concept, a substrate processing system may include a substrate processing apparatus including at least one process chamber configured to perform a process according to a process sequence, a database configured to store data associated with the process sequence of the substrate processing apparatus, a substrate processing congestion management apparatus configured to analyze a congestion cause of the substrate processing apparatus based on the data associated with the process sequence. The substrate processing congestion management apparatus includes at least one processor configured to receive the data associated with the process sequence from the database, to preprocess the received data, to divide the process sequence of the substrate processing apparatus into specific sections and determine whether congestion occurs in the specific sections, to set an initial suspected region corresponding to a section in which congestion occurs, analyze outliers in events occurring in the initial suspected region, deduce a final suspected region while updating the initial suspected region based on an event in which an outlier is identified, and determine, among the events, an event with a greatest contribution to the final suspected region as a congestion cause, and to notify the congestion cause, in which a suspected region includes a section that contributes to the congestion cause, and each of the events includes an action performed for processes by the substrate processing apparatus.

### BRIEF DESCRIPTION OF THE DRAWINGS

Embodiments will be more clearly understood from the following detailed description taken in conjunction with the accompanying drawings in which:

FIG. 1 is a schematic conceptual view of a substrate processing system according to an embodiment;

FIG. 2 is a schematic plan view of a substrate processing apparatus of FIG. 1;

FIG. 3 is a schematic block diagram of a substrate processing congestion management apparatus of FIG. 1;

FIG. 4 is a schematic block diagram of a congestion cause analysis unit of FIG. 3;

FIGS. 5A to 5F, 6A to 6D, and 7A to 7F are diagrams illustrating multiple examples showing a process of setting a final suspected region;

FIGS. 8A and 8B are diagrams to explain a process of determining a dominant event in a final suspected region;

FIG. 9 is a schematic flowchart of substrate processing congestion management operations according to an embodiment; and

FIG. 10 is a schematic flowchart of an operation of analyzing a congestion cause shown in FIG. 9.

### DETAILED DESCRIPTION OF THE EMBODIMENTS

Hereinafter, one or more embodiments are described in detail with reference to the attached drawings. Like reference numerals in the drawings denote like elements, and repeated descriptions thereof are omitted.

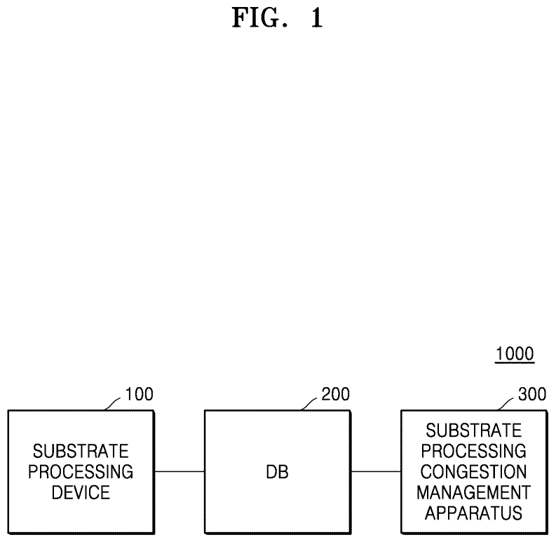

FIG. 1 is a schematic conceptual view of a substrate processing system according to an embodiment.

Referring to FIG. 1, a substrate processing system 1000 according to an embodiment may include a substrate processing apparatus 100, a database 200, and a substrate processing congestion management apparatus 300.

The substrate processing apparatus 100 may perform various processes on semiconductor substrates during semiconductor manufacturing processes. The substrate processing apparatus 100 of the inventive concept may perform a dry etching process, a chemical vapor deposition (CVD) process, a heat diffusion process, a photoresist development process, a cleaning process, and the like, but the processes are not limited thereto. The substrate processing apparatus may include various sensors and control devices that may control and maintain specific conditions required for individual processes.

For example, a substrate processing apparatus for a dry etching process may include a plasma generator using high-frequency power, a gas injection system capable of precise flow control, a pressure regulation device for maintaining a high-vacuum environment, a precise temperature control device for maintaining temperatures of wafers uniform, and the like. The above components may operate in an organically integrated manner to precisely control nanometer-level etching profiles.

The database 200 may be a system that systematically stores and manages data associated with the operation of the substrate processing apparatus 100. The database 200 of the inventive concept may be implemented based on, for example, a Relational Database Management System (RDBMS) and may have a structure for supporting real-time data processing and large-volume data analysis.

The stored data may primarily include process schedules, process recipes, process conditions, and sensing data. The process schedule data may include a work order of each substrate processing apparatus, expected processing times, and waiting times and may be utilized to optimize production scheduling. The process recipe data includes parameter setting values for each detailed operation of the process, process times, threshold values, and the like, and plays a crucial role in ensuring the reproducibility and stability of processes. The process condition data may include parameter values, such as temperatures, pressures, gas flow rates, and radio frequency (RF) power which are measured during actual processes, the parameter values being stored in a time-series format. The sensing data may include values that are measured in real time by in-line sensors and may be utilized for process error detection and quality management.

The substrate processing congestion management apparatus 300 may receive, from the database 200, data related to the substrate processing apparatus and analyze the same, thus managing process congestion. In other words, the substrate processing congestion management apparatus 300 may measure congestion times based on data related to the operations of the components of the substrate processing apparatus 100 to prevent congestion from recurring, and may automatically analyze the causes of congestion. When the congestion time exceeds a certain criterion, the substrate processing congestion management apparatus 300 may determine which component caused the congestion and propose corrective measures, which is described below.

The substrate processing congestion management apparatus 300 may identify whether congestion occurs during events of the substrate processing apparatus 100. An event refers to an action performed for processes by the substrate processing apparatus 100. To this end, an abnormal delay may be detected by comparing an actual process time with the process schedule or analyzing patterns in the sensing data.

When congestion occurs in the substrate processing apparatus 100, the substrate processing congestion management apparatus 300 may analyze the congestion cause. To this end, the substrate processing congestion management apparatus 300 may comprehensively analyze the process conditions, sensing data, device state, and the like, thus identifying the root cause of congestion. For example, the substrate processing congestion management apparatus 300 may identify abnormalities in specific sensor values, deviations in process parameters, and abrasion on device components.

The substrate processing congestion management apparatus 300 may suggest appropriate measures based on the analyzed cause of congestion. The substrate processing congestion management apparatus 300 may suggest measures, such as adjusting process parameters, requesting device inspection, and recommending component replacement. The substrate processing congestion management apparatus 300 may perform a function of notifying the relevant personnel of the aforementioned measures.

The substrate processing congestion management apparatus 300 may predict the occurrence of congestion, based on accumulated data, and propose preventive measures in advance. To this end, the efficiency of the entire process may be enhanced by preventing in advance potential congestion.

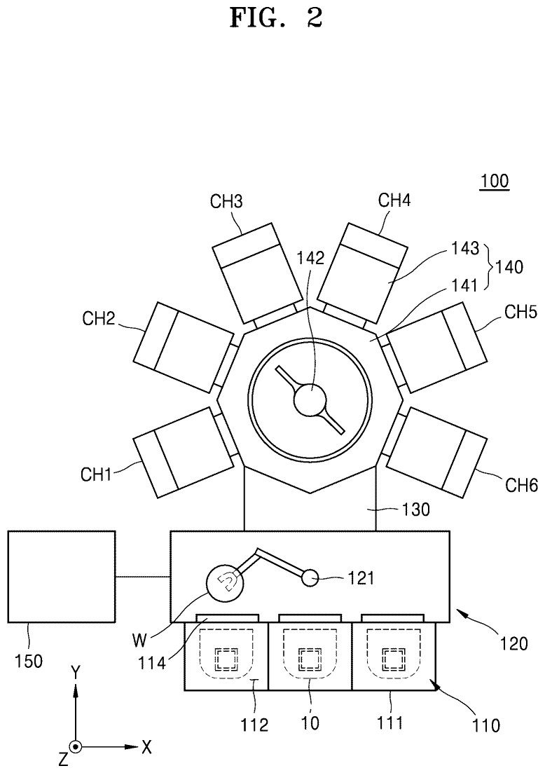

FIG. 2 is a schematic plan view of the substrate processing apparatus 100 of FIG. 1.

Referring to FIG. 2, the substrate processing apparatus 100 may include a front end module 110, a transport module 120, a load lock chamber 130, a manufacturing process module 140, and a control server 150.

The front end module 110 may include a load port 111 providing an inner space 112 where a substrate container 10 may be accommodated, and may adjust the inner space 112 of the load port 111 to vacuum pressure or atmospheric pressure.

The front end module 110 may fill the inner space 112 of the load port 111 or the interior of the substrate container 10 with nitrogen gas, inert gas, or clean dried air to increase the pressure in the inner space 112 and the interior of the substrate container 10 from vacuum pressure to atmospheric pressure.

The front end module 110 may maintain the inner space 112 at vacuum pressure while the manufacturing processes are performed on the semiconductor substrate W. In addition, the front end module 110 may forcibly discharge the gas from the inner space 112 to reduce the pressure in the inner space 112 of the load port 111 from atmospheric pressure to vacuum pressure.

In some embodiments, during the semiconductor manufacturing processes performed on the semiconductor substrate W, the front end module 110 may maintain the pressure in the inner space 112 at a vacuum pressure that is higher than the vacuum atmosphere in the manufacturing process module 140 but lower than external pressure (e.g., atmospheric pressure). Accordingly, gases or moisture left on the substrate container 10 waiting on the front end module 110 and a plurality of semiconductor substrates W accommodated in the substrate container 10 may be removed.

Although the pressure of the inner space 112 of the front end module 110 is not reduced to the vacuum atmosphere in the manufacturing process module 140, the contamination of the substrate container 10 and the semiconductor substrate W may be sufficiently removed without decreasing the productivity of the substrate processing apparatus 100 according to the process conditions.

The transport module 120 may be arranged at the rear end of the front end module 110. The transport module 120 may include a transport robot 121 that may freely rotate to load or unload the semiconductor substrates W stored in the substrate container 10 waiting on the front end module 110. The transport robot 121 of the transport module 120 may transport unprocessed semiconductor substrates W in the substrate container 10 to the load lock chamber 130 and may also transport, to the substrate container 10, semiconductor substrates W, on which manufacturing processes have been completed by the manufacturing process module 140 and which wait in the load lock chamber 130.

In some embodiments, the interior of the transport module 120 may be maintained in a vacuum state to prevent the semiconductor substrate W from being exposed to external air and contaminated while the transport robot 121 of the transport module 120 transports the semiconductor substrate W. For example, the pressure in a sealable space within the transport module 120 may be maintained at vacuum pressure.

Here, the front end module 110 may adjust the pressure in the load port 111 to be identical to the atmospheric pressure of the transport module 120 to prevent an atmospheric pressure change in the transport module 120 when a first door 114 is opened to move the semiconductor substrate W.

The load lock chamber 130 may be arranged between the transport module 120 and the manufacturing process module 140. The load lock chamber 130 may adjust the internal pressure to vacuum pressure to prevent atmospheric pressure changes in the transport module 120 and a transport chamber 141 of the manufacturing process module 140. A buffer stage (not shown), on which the semiconductor substrate W temporarily waits, may be installed in the load lock chamber 130, and the semiconductor substrate W transported by the transport robot 121 of the transport module 120 waits on the buffer stage while the pressure in the load lock chamber 130 is adjusted.

The load lock chamber 130 may form a vacuum atmosphere near the transport module 102 when the transport robot 121 of the transport module 120 loads or unloads the semiconductor substrate W, thus receiving unprocessed semiconductor substrates W from the transport robot 121 of the transport module 120. In addition, a vacuum atmosphere near the transport chamber 141 may be formed when a robot arm 142 in the transport chamber 141 of the manufacturing process module 140 loads or unloads the semiconductor substrate W, and the load lock chamber 130 may receive, from the robot arm 142, the semiconductor substrate W on which manufacturing processes have been completed.

The manufacturing process module 140 may be arranged at the rear end of the load lock chamber 130 and may include the transport chamber 141 and a plurality of process chambers 143. The manufacturing process module 140 may be a dry etch module, a chemical vapor deposition module, a thermal furnace, a developing module, or a cleaning module, but is not limited thereto.

The transport chamber 141 may be arranged between the load lock chamber 130 and the process chamber 143. The transport chamber 141 may include a robot arm 142 capable of performing free rotation and may transport the semiconductor substrate W waiting in the process chamber 143 and the load lock chamber 130.

The process chamber 143 may perform semiconductor manufacturing processes on the semiconductor substrate W. An access gate (not shown), through which the semiconductor substrate W is introduced or discharged, may be installed between the process chamber 143 and the transport chamber 141. A plurality of process chambers 143 may be installed along respective sides of the transport chamber 141. The process chamber 143 may include a first process chamber CH1 to a sixth process chamber CH6 arranged in a clockwise direction. FIG. 2 shows six process chambers 143, but one or more embodiments are not limited thereto.

The semiconductor substrate W, on which the semiconductor manufacturing processes are completed in the process chamber 143, may be transported by the robot arm 142 of the transport chamber 141 to the substrate container 10 waiting in the front end module 110. While the semiconductor substrate W is stored in the substrate container 10, the interior of the front end module 110 may be maintained in a vacuum state. Before the substrate container 10 is unloaded, the semiconductor substrate W, on which the semiconductor manufacturing processes are completed, waits in the front end module 110 that is in the vacuum state, and thus, gases or moisture remaining on the semiconductor substrate W may be removed.

In addition, pollutants remaining on the semiconductor substrate W, on which the semiconductor manufacturing processes are completed, may be removed while the semiconductor substrate W waits in the front end module 110; thus, unpressed semiconductor substrates W stored in the substrate container 10 may be prevented from being contaminated by corrosive gases released from the semiconductor substrate W on which the semiconductor manufacturing processes are completed.

The control server 150 may include a device controller, a module controller, and a switching hub connecting the device controller to the module controller. FIG. 2 shows that the control server 150 is arranged on the side surface of the load lock chamber 130, but the arrangement of the control server 150 is not limited thereto.

The control server 150 may be involved in the overall operations of the substrate processing apparatus 100 by transmitting control signals to individual components of the substrate processing apparatus 100, based on a control program, which is configured to implement various processes on the semiconductor substrate W on which the semiconductor manufacturing processes are performed, and the process recipe on which process condition data and the like are recorded. The substrate processing equipment 1000 is described in more detail below.

The semiconductor substrate W processed by the substrate processing apparatus 100 may typically be a wafer used to manufacture semiconductor devices. In addition to the components of the substrate processing apparatus 100 illustrated, multiple systems may be necessary to perform manufacturing processes required for the complete production of semiconductor integrated circuits or semiconductor chips. Here, general structures or those understood by one of ordinary skill in the art are omitted for clarity in explaining the inventive concept.

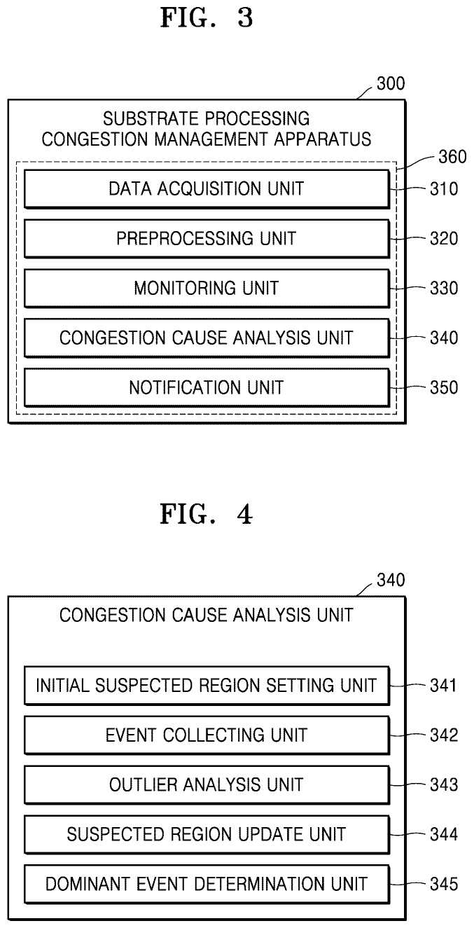

FIG. 3 is a schematic block diagram of the substrate processing congestion management apparatus 300 of FIG. 1.

Referring to FIG. 3, the substrate processing congestion management apparatus 300 according to an embodiment may be implemented using semiconductor circuits comprising one or more processors 360 (e.g., microprocessors, CPUs, ASICs, FPGAs, or other programmable logic devices) and associated memory storing program instructions. The processor 360 and memory may be implemented either as separate semiconductor circuits or as a single integrated semiconductor circuit. When executed by the processor 360, the program instructions provide the functionalities of the data acquisition unit 310, preprocessing unit 320, monitoring unit 330, congestion cause analysis unit 340, and notification unit 350.

The data acquisition unit 310 may be implemented using communication interfaces (e.g., network controllers, I/O controllers) configured to receive data from the database 200 through high-speed network connections. The communication interfaces may include buffer memory for temporary storage of received data.

The preprocessing unit 320 may be implemented using digital signal processors (DSPs) or arithmetic logic units (ALUs) specifically configured for high-speed data processing operations such as Fourier transforms, filtering, and normalization. The preprocessing unit 320 may include cache memory for storing intermediate processing results.

The monitoring unit 330 may be implemented using hardware timers and comparators configured to track process timing and detect timing anomalies in real-time. The monitoring unit 330 may include dedicated memory for storing predefined timing thresholds and measurement data.

The congestion cause analysis unit 340 may be implemented using parallel processing units optimized for statistical computations and pattern recognition. These may include vector processing units for efficient analysis of time-series data and dedicated hardware accelerators for outlier detection algorithms.

The notification unit 350 may be implemented using communication controllers capable of generating and transmitting alerts through various protocols (e.g., TCP/IP, industrial network protocols). The notification unit 350 may include memory for storing notification templates and logging notification history.

The processor 360 coordinates the operations of these units through a system bus, with direct memory access (DMA) controllers enabling efficient data transfer between units. The associated memory may include both volatile memory (e.g., DRAM, SRAM) for runtime operations and non-volatile memory (e.g., Flash, EEPROM) for storing program instructions and configuration data.

The data acquisition unit 310 of the processor 360 may collect, from the database 200, a massive amount of data associated with a process sequence of the substrate processing apparatus 100 in real time. The above data may include process parameters, device state information, sensor measurement values, wafer movement information, and the like. The data may be transmitted from the database 200 to the data acquisition unit 310 through a high-speed network. The data acquisition unit 310 may include a flexible interface that may efficiently process various types of data and may be incorporated with new types of sensors or devices even if they are newly added.

The data acquisition unit 310 may transmit, to the preprocessing unit 420, the data received from the database 200.

The preprocessing unit 320 of the processor 360 may preprocess the data received from the data acquisition unit 410. In other words, the preprocessing unit 320 may convert raw data received from the data acquisition unit 310 into a format suitable for analysis. The preprocessing unit 320 may apply advanced data processing techniques, such as noise removal, outlier detection, missing value processing, and normalization, during the preprocessing. For example, in the case of time-series data, features in a frequency domain may be extracted through Fourier transform or wavelet transform, thus providing additional insights. In addition, a dimensionality reduction technique may be applied to maintain critical features while reducing data complexity.

The monitoring unit 330 of the processor 360 may divide the process sequence of the substrate processing apparatus 100 into specific sections and determine whether congestion occurs in any of the sections. The monitoring unit 330 may define four monitoring sections based on the process chamber.

In at least one process chamber of the substrate processing apparatus 100, the monitoring unit 330 may set, as a first monitoring section, the period from the point in time when the semiconductor substrate W enters the process chamber to the point in time when a process starts within the process chamber. For example, during the first monitoring section, operations including wafer alignment and initial stabilization may be performed.

The monitoring unit 330 may define, as a second monitoring section, the period from the point in time when the process starts on the semiconductor substrate W in the process chamber to the point in time when the process ends. For example, the second monitoring section may refer to the period from the plasma generation to the completion of the etching process during a plasma etching process.

The monitoring unit 330 may define, as a third monitoring section, the period from the point in time when the process ends to the point in time when the semiconductor substrate W is discharged from the process chamber. For example, during the third monitoring section, operations such as residual gas removal and cooling may be performed.

The monitoring unit 330 may define, as a fourth monitoring section, the period from the point in time when the semiconductor substrate W is discharged from the process chamber to the point in time when the semiconductor substrate W enters another process chamber.

The congestion cause analysis unit 340 of the processor 360 may set an initial suspected region corresponding to the section where congestion occurs. The congestion cause analysis unit 340 may analyze outliers in events occurring in the initial suspected region. The congestion cause analysis unit 340 may update the initial suspected region based on the event in which the outlier is identified and may determine a final suspected region. The congestion cause analysis unit 340 may determine, as a congestion cause, the event that contributes the most to the final suspected region.

The notification unit 350 of the processor 360 may transmit the congestion cause, which is determined by the congestion cause analysis unit 340, to the relevant personnel. The notification unit 350 may further suggest specific measures. The notification unit 350 may propose measures to adjust the event cycle based on the content of the dominant event, modify process control parameters, or revise the process schedule. For example, the notification unit 350 may suggest adjusting the inspection cycle of the substrate processing apparatus when the dominant event is related to recurring malfunctions of the substrate processing apparatus. When congestion results from deviations in process parameters, the notification unit 350 may suggest optimized parameter values. In addition, when an issue is detected in the general process flow, the notification unit 350 may recommend readjusting the production schedule. Such a notification system may enable fast and effective countermeasures against congestion.

The substrate processing congestion management apparatus 300 according to an embodiment may provide the following technical effects:
Real-time adjustment of process parameters to optimize chamber conditions
Automated triggering of equipment maintenance checks
Intelligent recommendation of component replacement timing
Dynamic revision of process scheduling based on congestion analysis
Improvement of overall substrate processing efficiency through automated control

FIG. 4 is a schematic block diagram of the congestion cause analysis unit 340 of FIG. 3.

Referring to FIG. 4, the congestion cause analysis unit 340 may include an initial suspected region setting unit 341, an event collecting unit 342, an outlier analysis unit 343, a suspected region update unit 344, and a dominant event determination unit 345.

The initial suspected region setting unit 341 may set an initial suspected region in the monitoring section in which congestion occurs, the monitoring section being selected from among the first monitoring section to the fourth monitoring section. In other words, the initial suspected region setting unit 341 may define an initial analysis target region based on the section in which congestion occurs, the section being identified by the monitoring unit 330.

More specifically, when congestion occurs in the first monitoring section, the initial suspected region setting unit 341 may set, as the initial suspected region, the period from the point in time when the semiconductor substrate enters the process chamber to when the semiconductor substrate is discharged from the process chamber.

When congestion occurs in the second monitoring section, the initial suspected region setting unit 341 may set, as the initial suspected region, the period from the point in time when the semiconductor substrate enters the process chamber to when the semiconductor substrate is discharged from the process chamber.

When congestion occurs in the third monitoring section, the initial suspected region setting unit 341 may set, as the initial suspected region, the period from the point in time when the semiconductor substrate enters the process chamber to when the semiconductor substrate enters another process chamber.

When congestion occurs in the fourth monitoring section, the initial suspected region setting unit 341 may set, as the initial suspected region, the period from the point in time when the process ends in the process chamber to when the process ends in the other process chamber.

The initial suspected region setting unit 341 may designate a specific section, in which congestion is detected, from the segmented monitoring sections including the first monitoring section to the fourth monitoring section. Such an approach may enhance the effectiveness of subsequent analysis by clarifying the initial analysis point.

The event collecting unit 342 may collect events, which are executed in the initial suspected region, from the database 200 through the data acquisition unit 310. The event collecting unit 342 may collect all events occurring in the initial suspected region. Here, an event refers to an individual action performed for a process in the substrate processing apparatus. For example, an event may include operations such as gas injection, pumping, slit valve opening, lifting up, lifting down, pressure adjustment, and RF power application.

The outlier analysis unit 343 may analyze whether there is an abnormality in the execution time of the event or the elapsed time between the events. That is, the outlier analysis unit 343 may analyze temporal characteristics of the collected events. Specifically, the outlier analysis unit 343 may compare a scheduled execution time with an actual execution time of each event occurring in the initial suspected region and determine whether there is an abnormality. When the actual event execution time exceeds the scheduled execution time, the outlier analysis unit 343 may determine that there is an abnormality in the event.

In addition, the outlier analysis unit 343 may check whether the elapsed time between consecutive events exceeds the scheduled elapsed time. When the actual elapsed time between the events exceeds the scheduled elapsed time, the outlier analysis unit 343 may determine that there is an abnormality between the events.

The outlier analysis unit 343 may detect subtle abnormalities by using machine-learning algorithms and statistical techniques. For example, the outlier analysis unit 343 may identify an outlier by applying a Z-score technique or an Isolation Forest algorithm.

The suspected region update unit 344 may set the execution time of the event with an abnormality or the elapsed time between abnormal events as a suspected region and may update the initial suspected region with the suspected region. The suspected region update unit 344 may set the region, where the suspected regions overlap, as the final suspected region.

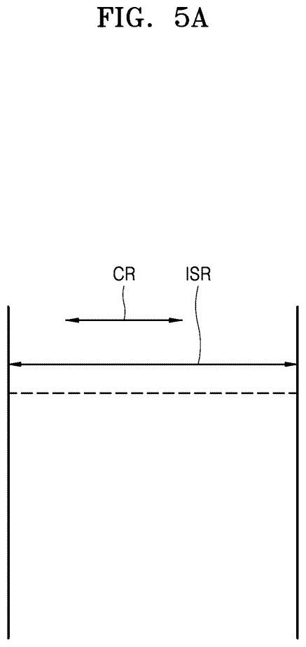

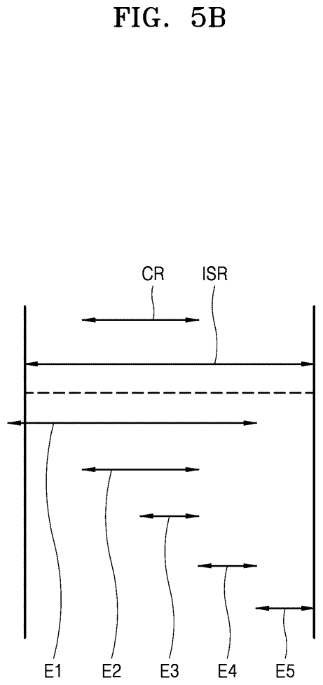

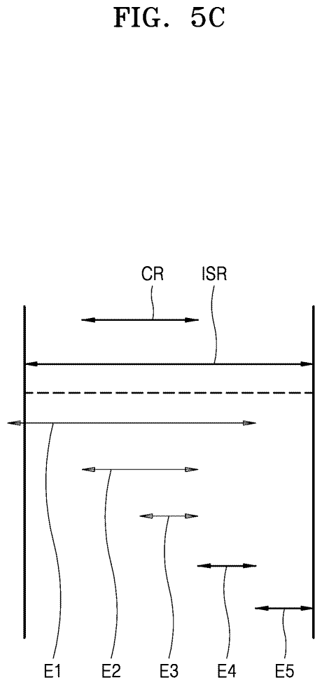

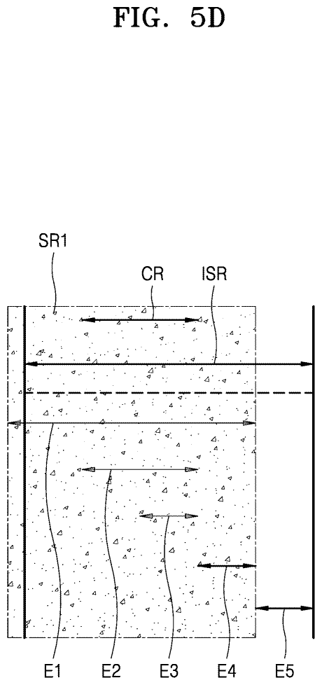

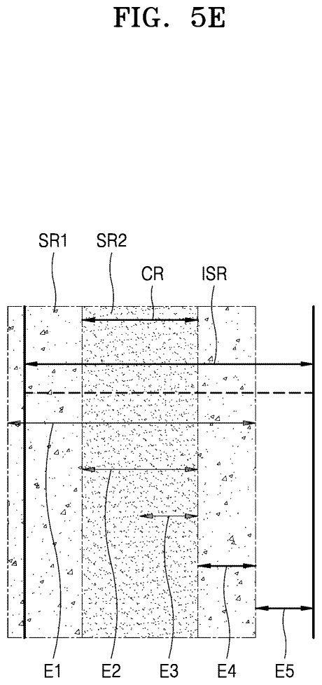

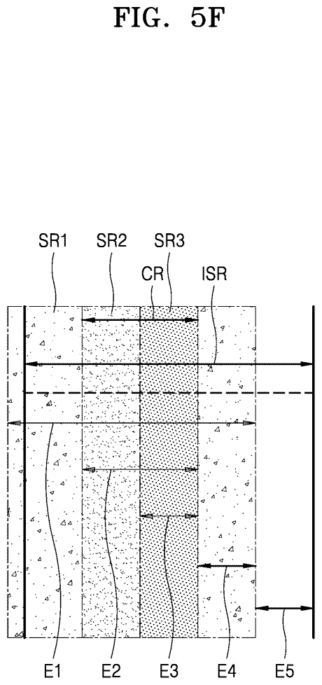

In other words, the suspected region update unit 344 may precisely update the initial suspected region based on the outlier analysis result. The suspected region update unit 344 may define, as a new suspected region, the execution time of the event with an abnormality or the abnormal execution time between events. By repeatedly performing the above processes, the region where the suspected regions overlap may be confirmed as the final suspected region. Thus, the time slot that is most likely to include the root cause of congestion may be precisely identified. This will be described in detail with reference to FIGS. 5A to 7F.

The dominant event determination unit 345 may set, as a dominant event, the event with the greatest contribution to the final suspected region. The dominant event determination unit 345 may determine the contribution of events by calculating the difference between the start point and the termination point of each event based on the start point and the termination point of the final suspected region, thus setting the event with the greatest contribution as the dominant event.

The dominant event determination unit 345 may identify the event that has the greatest impact on the congestion in the final suspected region. The dominant event determination unit 345 may calculate the contribution by comparing the start point and the termination point of each event with the boundary of the final suspected region. In detail, the dominant event determination unit 345 may calculate the contribution by comprehensively considering the difference between the start point of each event and the start point of the final suspected region and the difference between the termination point of each event and the termination point of the final suspected region. The notification unit 350 may finally determine the event with the greatest contribution as the dominant event and present the dominant event as the root cause of congestion.

FIGS. 5A to 5F, 6A to 6D, and 7A to 7F are diagrams illustrating multiple examples showing the process of setting a final suspected region.

FIGS. 5A to 5F are diagrams illustrating the process of setting the final suspected region when there is a single cause of congestion.

Referring to FIG. 5A, when the monitoring unit 330 determines that congestion CR occurs in the first monitoring section, the initial suspected region setting unit 341 may set a section corresponding to the first monitoring section as an initial suspected region ISR. The initial suspected region ISR corresponding to the first monitoring section is the period from the point in time when the semiconductor substrate enters the process chamber to when the semiconductor substrate is discharged from the process chamber.

Referring to FIG. 5B, the event collecting unit 342 may collect all events executed in the initial suspected region ISR from the database 200 through the data acquisition unit 310. The events executed in the initial suspected region ISR may include a first event E1, a second event E2, a third event E3, a fourth event E4, and a fifth event E5.

Referring to FIG. 5C, the outlier analysis unit 343 may analyze whether there is an abnormality in the execution time of each of the first event E1, the second event E2, the third event E3, the fourth event E4, and the fifth event E5. In other words, the outlier analysis unit 343 may check whether the actual execution times of the first event E1, the second event E2, the third event E3, the fourth event E4, and the fifth event E5 exceed their respective scheduled execution times. The outlier analysis unit 343 may determine that the first event E1, the second event E2, and the third event E3 have abnormalities when the execution times of the first event E1, the second event E2, and the third event E3 exceed their scheduled execution times.

Referring to FIGS. 5D to 5F, the suspected region update unit 344 may update the suspected region based on the first event E1, the second event E2, and the third event E3 in which abnormalities are detected.

Referring to FIG. 5D, the suspected region update unit 344 may set the execution time of the first event E1 as a first suspected region SR1. The first suspected region SR1 refers to the section from the start point of the first event E1 to the termination point thereof. The termination point of the first event E1 is within the initial suspected region ISR, but the start point of the first event E1 is outside the initial suspected region ISR. Therefore, a portion of the first suspected region SR1 may overlap the initial suspected region ISR, and another portion of the first suspected region SR1 may not overlap the initial suspected region ISR.

Referring to FIG. 5E, the suspected region update unit 344 may set the execution time of the second event E2 as a second suspected region SR2. The second suspected region SR2 refers to the section from the start point of the second event E2 to the termination point thereof. The second suspected region SR2 may be included not only in the first suspected region SR1 but also in the initial suspected region ISR.

Referring to FIG. 5F, the suspected region update unit 344 may set the execution time of the third event E3 as a third suspected region SR3. The third suspected region SR3 refers to the section from the start point of the third event E3 to the termination point thereof. The third suspected region SR3 may be included in the first suspected region SR1, the second suspected region SR2, and the initial suspected region ISR.

The suspected region update unit 344 may compare the first suspected region SR1, the second suspected region SR2, the third suspected region SR3, and the initial suspected region ISR with each other and may set the third suspected region SR3, where all of the suspected regions overlap each other, as the final suspected region.

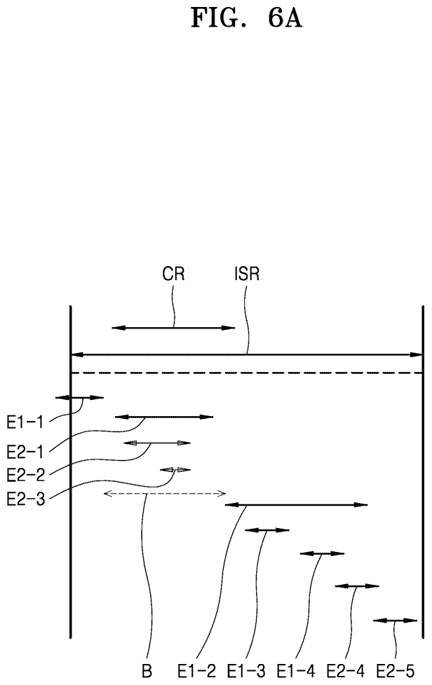

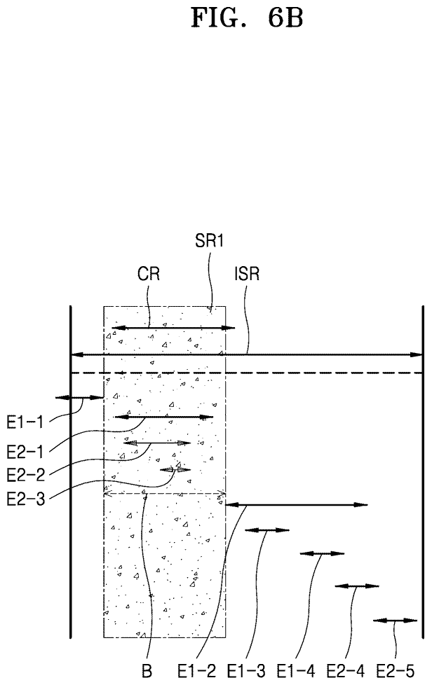

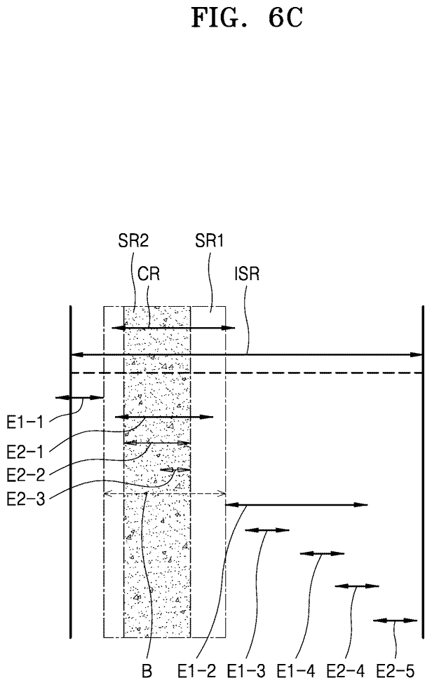

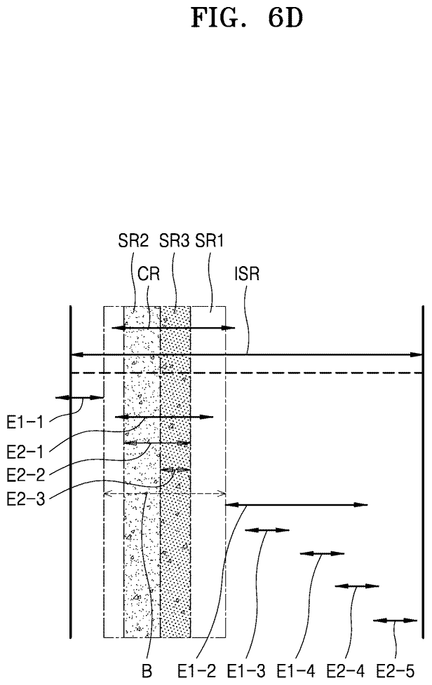

FIGS. 6A to 6D are diagrams to explain a process of setting a final suspected region when a congestion cause is identified between events.

Referring to FIG. 6A, when the monitoring unit 330 determines that congestion CR occurs in the first monitoring section, the initial suspected region setting unit 341 may set a section corresponding to the first monitoring section as an initial suspected region ISR. The initial suspected region ISR corresponding to the first monitoring section is a period from the point in time when the semiconductor substrate enters the process chamber to when the semiconductor substrate is discharged from the process chamber.

The event collecting unit 342 may collect all events executed in the initial suspected region ISR from the database 200 through the data acquisition unit 310. The events executed in the initial suspected region ISR may include a first event E1-1, a second event E1-2, a third event E1-3, a fourth event E1-4, a fifth event E2-1, a sixth event E2-2, a seventh event E2-3, an eighth event E2-4, and a ninth event E2-5.

The outlier analysis unit 343 may analyze whether there are abnormalities in the execution times of the first event E1-1, the second event E1-2, the third event E1-3, the fourth event E1-4, the fifth event E2-1, the sixth event E2-2, the seventh event E2-3, the eighth event E2-4, and the ninth event E2-5. In addition, the outlier analysis unit 343 may analyze whether the elapsed time between events is abnormal.

In other words, the outlier analysis unit 343 may identify whether the actual execution times of the first event E1-1, the second event E1-2, the third event E1-3, the fourth event E1-4, the fifth event E2-1, the sixth event E2-2, the seventh event E2-3, the eighth event E2-4, and the ninth event E2-5 exceed their respective scheduled execution times. Moreover, the outlier analysis unit 343 may check whether the actual elapsed times between events exceed the scheduled elapsed times.

When the execution times of the sixth event E2-2 and the seventh event E2-3 exceed their respective scheduled execution times, the outlier analysis unit 343 may determine that the sixth event E2-2 and the seventh event E2-3 are abnormal.

When the elapsed time between the first event E1-1 and the second event E1-2 exceeds the scheduled elapsed time, the outlier analysis unit 343 may determine that a section B between the first event E1-1 and the second event E1-2 is abnormal.

Referring to FIGS. 6B to 6D, the suspected region update unit 344 may update the suspected region within the section B that spans between the sixth event E2-2 and the seventh event E2-3 and between the first event E1-1 and the second event E1-2, where abnormalities are detected in the sixth event E2-2, the seventh event E2-3, the first event E1-1, and the second event E1-2.

Referring to FIG. 6B, the suspected region update unit 344 may set, as the first suspected region SR1, the section B between the first event E1-1 and the second event E1-2. The first suspected region SR1 refers to the section from the termination point of the first event E1-1 to the start point of the second event E1-2. The first suspected region SR1 may be included in the initial suspected region ISR.

Referring to FIG. 6C, the suspected region update unit 344 may set the elapsed time of the sixth event E2-2 as the second suspected region SR2. The second suspected region SR2 refers to the section from the start point of the sixth event E2-2 to the termination point of the sixth event E2-2. The second suspected region SR2 may be included not only in the first suspected region SR1 but also in the initial suspected region ISR.

Referring to FIG. 6D, the suspected region update unit 344 may set the elapsed time of the seventh event E3-3 as the third suspected region SR3. The third suspected region SR3 refers to the section from the start point of the seventh event E3-3 to the termination point thereof. The third suspected region SR3 may be included in the first suspected region SR1, the second suspected region SR2, and the initial suspected region ISR.

The suspected region update unit 344 may compare the first suspected region SR1, the second suspected region SR2, the third suspected region SR3, and the initial suspected region ISR and may set the third suspected region SR3, where all of the suspected regions overlap each other, as the final suspected region.

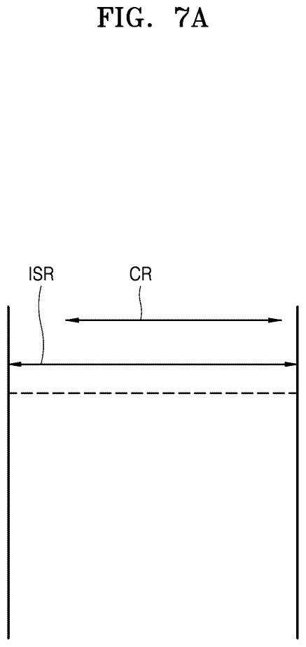

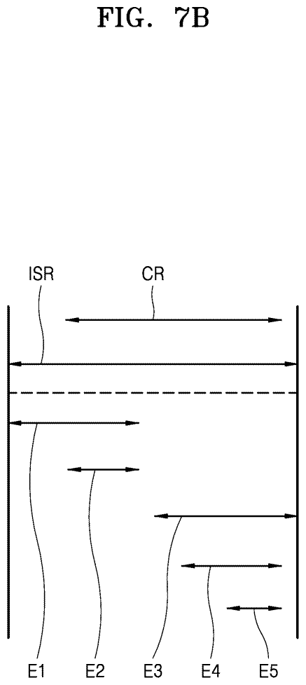

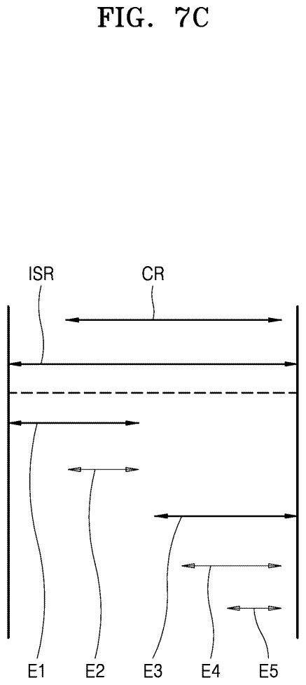

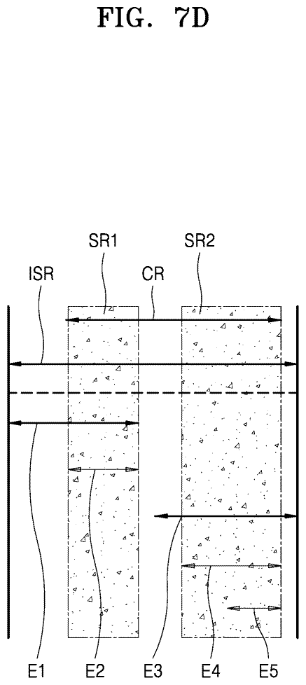

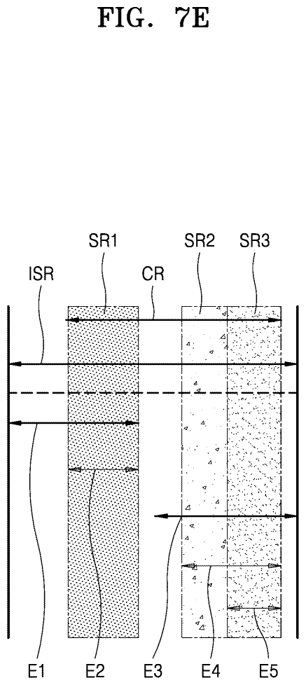

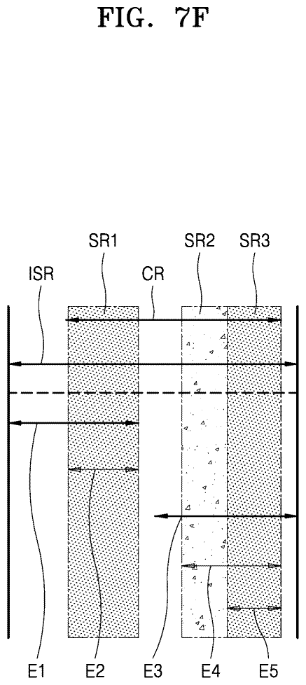

FIGS. 7A to 7F are diagrams to explain a process of determining a final suspected region when multiple causes of congestion are present.

Referring to FIG. 7A, when the monitoring unit 330 determines that congestion CR occurs in the first monitoring section, the initial suspected region setting unit 341 may set a section corresponding to the first monitoring section as an initial suspected region ISR. The initial suspected region ISR corresponding to the first monitoring section is the period from the point in time when the semiconductor substrate enters the process chamber to when the semiconductor substrate is discharged from the process chamber.

Referring to FIG. 7B, the event collecting unit 342 may collect all events executed in the initial suspected region ISR from the database 200 through the data acquisition unit 310. The events executed in the initial suspected region ISR may include a first event E1, a second event E2, a third event E3, a fourth event E4, and a fifth event E5.

Referring to FIG. 7C, the outlier analysis unit 343 may analyze whether there are abnormalities in the execution times of the first event E1, the second event E2, the third event E3, the fourth event E4, and the fifth event E5. In other words, the outlier analysis unit 343 may check whether the actual execution times of the first event E1, the second event E2, the third event E3, the fourth event E4, and the fifth event E5 exceed their respective scheduled execution times. The outlier analysis unit 343 may determine that there are abnormalities in the second event E2, the fourth event E4, and the fifth event E5 when the execution times of the second event E2, the fourth event E4, and the fifth event E5 exceed their scheduled execution times.

Referring to FIGS. 7D to 7F, the suspected region update unit 344 may update the suspected region based on the second event E2, the fourth event E4, and the fifth event E5 in which abnormalities are detected.

Referring to FIG. 7D, the suspected region update unit 344 may set the execution time of the second event E2 as the first suspected region SR1. The first suspected region SR1 refers to the section from the start point of the second event E2 to the termination point of the second event E2. The first suspected region SR1 may be included in the initial suspected region ISR.

The suspected region update unit 344 may set the execution time of the fourth event E4 as the second suspected region SR2. The second suspected region SR2 refers to the section from the start point of the fourth event E4 to the termination point thereof. The second suspected region SR2 may be included in the initial suspected region ISR.

Both the first suspected region SR1 and the second suspected region SR2 are included in the initial suspected region ISR, but they do not overlap each other.

Referring to FIG. 7E, the suspected region update unit 344 may set the execution time of the fifth event E5 as the third suspected region SR3. The third suspected region SR3 refers to the section from the start point of the fifth event E5 to the termination point thereof. The third suspected region SR3 is included in the second suspected region SR2 and the initial suspected region ISR, but not included in the first suspected region SR1. In other words, the third suspected region SR3 may not overlap the first suspected region SR1, but may overlap the second suspected region SR2.

Referring to FIG. 7F, the suspected region update unit 344 may compare the first suspected region SR1, the second suspected region SR2, the third suspected region SR3, and the initial suspected region ISR, thus determining the final suspected region. The suspected region update unit 344 may set, as the final suspected region, the third suspected region SR3 that overlaps the initial suspected region ISR and the second suspected region SR2. In addition, when the first suspected region SR1 does not overlap another suspected region but overlaps only the initial suspected region ISR, the suspected region update unit 344 may set the first suspected region SR1 as the final suspected region. In other words, when a plurality of suspected regions exist without overlapping each other, the suspected region update unit 344 may set suspected regions that do not overlap as the final suspected region.

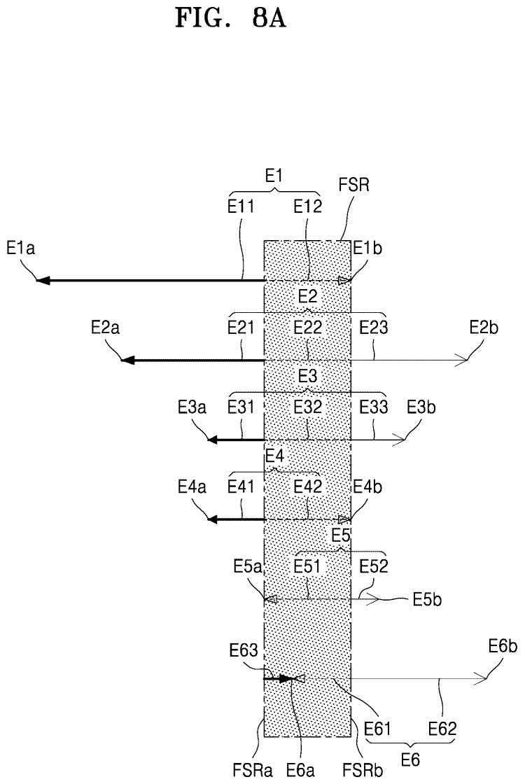

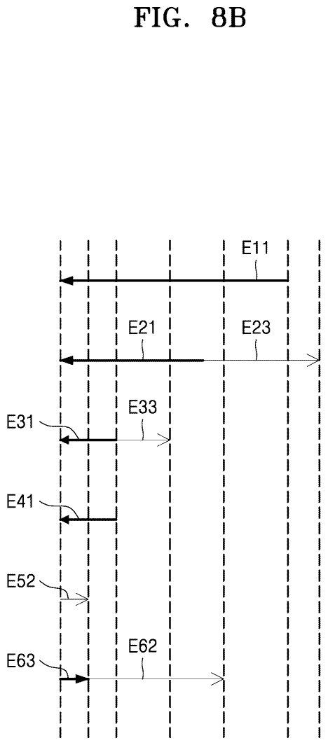

FIGS. 8A and 8B are diagrams to explain a process of determining a dominant event in a final suspected region.

Referring to FIG. 8A, the dominant event determination unit 345 may set, as a dominant event, the event with the greatest contribution to a final suspected region FSR. The dominant event determination unit 345 may calculate the contribution of each event by calculating the difference between the start point and the termination point of each event based on a start point FSRa and a termination point FSRb of the final suspected region FSR and may then set the event with the greatest contribution as the dominant event.

The dominant event determination unit 345 may calculate the contribution by using Equation (1) below.

Contribution=−(|Aₛₜₐᵣₜ−Bₛₜₐᵣₜ|+|A_{end}−B_{end}|) . . . Equation (1)

Here, Aₛₜₐᵣₜ represents the start point of the final suspected region, Bₛₜₐᵣₜ represents the start point of an event, A_{end} represents the termination point of the final suspected region, and B_{end} represents the termination point of the event.

Depending on whether the final suspected region FSR overlaps the first event E1, the first event E1 may include a first portion E11 that does not overlap the final suspected region FSR and a second portion E12 that overlaps the final suspected region FSR.

Because the termination point FSRb of the final suspected region FSR is identical to a termination point E1b of the first event E1, the contribution of the first event E1 may be represented by the first portion E11 that is the value obtained by subtracting the start point E1a of the first event E1 from the start point FSRa of the final suspected region FSR.

Depending on whether the final suspected region FSR overlaps the second event E2, the second event E2 may include a first portion E21 and a third portion E23, which do not overlap the final suspected region FSR, and a second portion E22, which overlaps the final suspected region FSR.

The contribution of the second event E2 may be represented by the sum of the first portion E21, which is the value obtained by subtracting the start point E2a of the second event E2 from the start point FSRa of the final suspected region FSR, and the third portion E23, which is the value obtained by subtracting the termination point E2b of the second event E2 from the termination point FSRb of the final suspected region FSR.

Depending on whether the final suspected region FSR overlaps the third event E3, the third event E3 may include a first portion E31 and a third portion E33, which do not overlap the final suspected region FSR, and a second portion E32, which overlaps the final suspected region FSR.

The contribution of the third event E3 may be represented by the sum of the first portion E21, which is the value obtained by subtracting the start point E3a of the third event E3 from the start point FSRa of the final suspected region FSR, and the third portion E23, which is the value obtained by subtracting the termination point E3b of the third event E3 from the termination point FSRb of the final suspected region FSR.

Depending on whether the final suspected region FSR overlaps the fourth event E4, the fourth event E4 may include a first portion E41 that does not overlap the final suspected region FSR and a second portion E42 that overlaps the final suspected region FSR.

Because the termination point FSRb of the final suspected region FSR is identical to a termination point E4b of the fourth event E4, the contribution of the fourth event E4 may be represented by the first portion E41 that is the value obtained by subtracting the start point E4a of the fourth event E4 from the start point FSRa of the final suspected region FSR.

Depending on whether the final suspected region FSR overlaps the fifth event E5, the fifth event E5 may include a first portion E51 that does not overlap the final suspected region FSR and a second portion E52 that overlaps the final suspected region FSR.

Because the start point FSRa of the final suspected region FSR is identical to a start point E5a of the fifth event E5, the contribution of the fifth event E5 may be represented by the second portion E52 that is the value obtained by subtracting the termination point E5b of the fifth event E5 from the termination point FSRb of the final suspected region FSR.

Depending on whether the final suspected region FSR overlaps the sixth event E6, the sixth event E6 may include a first portion E61 that overlaps the final suspected region FSR and a second portion E62 that does not overlap the final suspected region FSR.

The contribution of the sixth event E6 may be represented by the sum of the third portion E63, which is the value obtained by subtracting the start point E6a of the sixth event E6 from the start point FSRa of the final suspected region FSR, and the second portion E62, which is the value obtained by subtracting the termination point E6b of the sixth event E6 from the termination point FSRb of the final suspected region FSR.

FIG. 8B shows a comparison of the contributions of respective events in FIG. 8A.

Referring to FIG. 8B, the contribution of the first event E1 may be the first portion E11 as described above with reference to FIG. 8A. The contribution of the second event E2 may be the sum of the first portion E21 and the second portion E23. The contribution of the third event E3 may be the sum of the first portion E31 and the third portion E33. The contribution of the fourth event E4 may be the first portion E41. The contribution of the fifth event E5 may be the second portion E52. The contribution of the sixth event E6 may be the sum of the second portion E62 and the third portion E63.

Because the contribution is expressed as a negative value as in Equation (1), a smaller length in FIG. 8B may indicate a greater contribution. Therefore, the fifth event E5 having the smallest length may be determined as the dominant event.

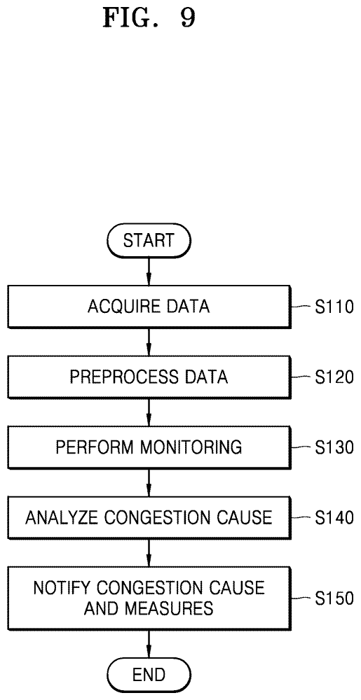

FIG. 9 is a schematic flowchart of substrate processing congestion management operations according to an embodiment.

Referring to FIG. 9, the substrate processing congestion management operations according to an embodiment may include operation S110 of acquiring data, operation S120 of performing data pre-processing, operation S130 of performing monitoring, operation S140 of analyzing a cause of congestion, and operation S150 of notifying the cause of congestion and proposed measures.

In operation S110 of acquiring data, a large amount of data related to the process sequence of the substrate processing apparatus 100 may be collected from the database 200 in real time. The above data may include process parameters, device state information, sensor measurement values, wafer movement information, and the like. The data may be transmitted from the database 200 to the data acquisition unit 310 through a high-speed network.

In operation S120 of performing data pre-processing, the data from the data acquisition unit 310 may be preprocessed. In other words, in operation S120 of performing data pre-processing, raw data received from the data acquisition unit 310 may be converted into a form suitable for analysis. In operation S120 of performing data pre-processing, advanced data processing techniques, such as noise removal, outlier detection, missing value processing, and normalization, may be applied. For example, in the case of time series data, features in a frequency domain may be extracted through Fourier transform or wavelet transform, thus providing additional insights. In addition, a dimensionality reduction technique may be applied to maintain critical features while reducing data complexity.

In operation S130 of performing monitoring, the process sequence of the substrate processing apparatus 100 may be divided into specific sections and determine whether congestion occurs in the divided sections. In operation S130 of performing monitoring, four monitoring sections may be set based on the process chamber.

In operation S130 of performing monitoring, the period from the point in time when the semiconductor substrate W enters at least one process chamber of the substrate processing apparatus 100 to when the process starts within the process chamber may be set as the first monitoring section. For example, during the first monitoring section, operations such as wafer alignment and initial stabilization may be performed. In operation S130 of performing monitoring, the period from the point in time when the process starts on the semiconductor substrate W in the process chamber to when the process ends may be set as the second monitoring section. For example, the second monitoring section may refer to the period from the plasma generation to the completion of the etching process during a plasma etching process. In operation S130 of performing monitoring, the period from the point in time when the process ends to the point in time when the semiconductor substrate W is discharged from the process chamber may be defined as the third monitoring section. For example, operations such as residual gas removal and cooling may be performed during the third monitoring section. In operation S130 of performing monitoring, the period from the point in time when the semiconductor substrate W is discharged from the process chamber to the point in time when the semiconductor substrate W enters a different process chamber may be defined as the fourth monitoring section.

In operation S140 of analyzing the congestion cause, an initial suspected region corresponding to the section where congestion occurs may be defined. In operation S140 of analyzing the congestion cause, outliers in the events occurring in the initial suspected region may be analyzed. In operation S140 of analyzing the congestion cause, the final suspected region may be derived while updating the initial suspected region based on the event in which the outlier is detected. In operation S140 of analyzing the congestion cause, the event with the greatest contribution to the final suspected region may be determined as the cause of congestion.

In operation S150 of notifying the cause of congestion and proposed measures, the congestion cause determined by the congestion cause analysis unit 340 may be transmitted to the relevant personnel. Operation S150 of notifying the cause of congestion and proposed measures may further include proposing specific measures. In operation S150 of notifying the cause of congestion and proposed measures, measures may be suggested to adjust the event cycle based on the content of the dominant event, the process control parameters, or the process schedule.

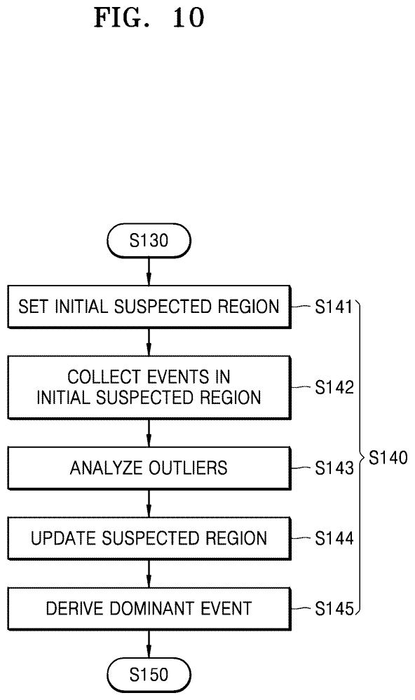

FIG. 10 is a schematic flowchart of an operation of analyzing a congestion cause shown in FIG. 9.

Referring to FIG. 10, as an example, operation S140 of analyzing the congestion cause may include operation S141 of setting an initial suspected region, operation S142 of collecting events, operation S143 of analyzing outliers, operation S144 of updating a suspected region, and operation S145 of determining a dominant event.

In operation S141 of setting an initial suspected region, the initial suspected region may be set in a monitoring section in which congestion occurs, the monitoring section being selected from among the first monitoring section to the fourth monitoring section. In other words, in operation S141 of setting an initial suspected region, an initial analysis target region may be defined based on the section in which the congestion occurs, the section being identified in operation S130 of performing monitoring.

In operation S142 of collecting events, the events executed in the initial suspected region may be collected from the database 200 through the data acquisition unit 310. In operation S142 of collecting events, all events occurring in the initial suspected region may be collected. Here, an event refers to an individual action performed for a process in the substrate processing apparatus. For example, an event may include operations such as gas injection, pumping, slit valve opening, lifting up, lifting down, pressure adjustment, and RF power application.

Operation S143 of analyzing outliers may include determining whether there are abnormalities in the execution times of the events or the elapsed time between the events. That is, operation S143 of analyzing outliers may include analyzing temporal characteristics of the collected events. Specifically, operation S143 of analyzing outliers may include comparing the actual execution time of each event occurring in the initial suspected region with the scheduled execution time to determine any abnormalities. In operation S143 of analyzing outliers, when the actual execution time of the event exceeds the scheduled execution time, it may be determined that there is an abnormality in the event.

In addition, in operation S143 of analyzing outliers, the elapsed time between consecutive events exceeds the scheduled elapsed time. In operation S143 of analyzing outliers, when the actual elapsed time between the events exceeds the scheduled elapsed time, it may be determined that there is an abnormality between the events.

Operation S144 of updating a suspected region may include setting, as a suspected region, an execution time of an abnormal event or an elapsed time between abnormal events and updating the initial suspected region with the above suspected region. The suspected region update unit 344 may set the region, where the suspected regions overlap, as a final suspected region.

In other words, the suspected region update unit 344 may precisely update the initial suspected region based on the outlier analysis result. The suspected region update unit 344 may define, as a new suspected region, the execution time of the event with an abnormality or the abnormal execution time between events. By repeatedly performing the above processes, the region where the suspected regions overlap may be confirmed as the final suspected region. Thus, the time slot that is most likely to include the root cause of congestion may be precisely identified.

Operation S145 of determining a dominant event may include setting, as a dominant event, an event with the greatest contribution to the final suspected region. Operation S145 of determining a dominant event may include determining the contribution of events by calculating the difference between the start point and the termination point of each event based on the start point and the termination point of the final suspected region and setting the event with the greatest contribution as the dominant event.

In operation S145 of determining a dominant event, an event, which has the greatest impact on the congestion in the final suspected region, may be identified. In operation S145 of determining a dominant event, the contribution may be calculated by comparing the start point and the termination point of each event with the boundary of the final suspected region. In detail, in operation S145 of determining a dominant event, the contribution may be calculated by comprehensively considering the difference between the start point of each event and the start point of the final suspected region and the difference between the termination point of each event and the termination point of the final suspected region. Operation S150 of notifying the congestion cause and proposed measures may include determining the event with the greatest congestion as the dominant event and presenting the dominant event as the root cause of congestion.

While the inventive concept has been particularly shown and described with reference to embodiments thereof, it will be understood that various changes in form and details may be made therein without departing from the spirit and scope of the following claims.

What is claimed is:

1. A substrate processing congestion management apparatus comprising:
at least one processor configured to:
divide a process sequence of a substrate processing apparatus into specific sections and determine whether congestion occurs in the specific sections;
set an initial suspected region corresponding to a section in which the congestion occurs, analyze outliers in events occurring in the initial suspected region, deduce a final suspected region while updating the initial suspected region based on an event in which an outlier is identified, and determine, among the events, an event with a greatest contribution to the final suspected region as a congestion cause; and
notify the congestion cause and automatically control the substrate processing apparatus to reduce process congestion and improve substrate processing throughput, based on the determined congestion cause by performing at least one of:
adjusting gas flow parameters of at least one process chamber in the substrate processing apparatus;
modifying radio frequency (RF) power delivery timing in the at least one process chamber;
controlling pressure ramping rates between process steps performed by the substrate processing apparatus;
updating transfer robot scheduling between adjacent process chambers of the at least one process chamber; or
modifying maintenance timing of components in the at least one process chamber.

2. The substrate processing congestion management apparatus of claim 1, wherein a suspected region includes a section that contributes to the congestion cause.

3. The substrate processing congestion management apparatus of claim 1, wherein each of the events includes an action performed for processes in the substrate processing apparatus.

4. The substrate processing congestion management apparatus of claim 1, wherein the at least one processor is further configured to:
set, as a first monitoring section, a period from a point in time when a semiconductor substrate enters at least one process chamber of the substrate processing apparatus to a point in time when a process starts within the at least one process chamber;
set, as a second monitoring section, a period from a point in time when the process starts on the semiconductor substrate within the at least one process chamber to a point in time when the process ends;
set, as a third monitoring section, a period from a point in time when the process ends to a point in time when the semiconductor substrate is discharged from the at least one process chamber; and
set, as a fourth monitoring section, a period from a point in time when the semiconductor substrate is discharged from the at least one process chamber to a point in time when the semiconductor substrate enters a different process chamber.

5. The substrate processing congestion management apparatus of claim 4, wherein the at least one processor is further configured to:
set the initial suspected region corresponding to a monitoring section, in which the congestion occurs, from among the first monitoring section to the fourth monitoring section;
collect the events executed in the initial suspected region;
analyze whether there is an abnormality in execution times of the events or an elapsed time between the events;
set an execution time of an abnormal event or an elapsed time between abnormal events as suspected regions, update the initial suspected region with the suspected regions, and set a section, in which the suspected regions overlap, as a final suspected region; and
set, as a dominant event, the event with the greatest contribution to the final suspected region.

6. The substrate processing congestion management apparatus of claim 5, wherein the at least one processor is further configured to:
when the congestion occurs in the first monitoring section, set a period from a point in time, when the semiconductor substrate enters the at least one process chamber, to a point in time, when the semiconductor substrate is discharged from the at least one process chamber, as the initial suspected region;
when the congestion occurs in the second monitoring section, set a period from a point in time, when the semiconductor substrate enters the at least one process chamber, to a point in time, when the semiconductor substrate is discharged from the at least one process chamber, as the initial suspected region;
when the congestion occurs in the third monitoring section, set a period from a point in time, when the semiconductor substrate enters the at least one process chamber, to a point in time, when the semiconductor substrate enters the different process chamber, as the initial suspected region; and
when the congestion occurs in the fourth monitoring section, set a period from a point in time, when a process ends in the at least one process chamber, to a point in time, when a process ends in the different process chamber, as the initial suspected region.

7. The substrate processing congestion management apparatus of claim 6, wherein the at least one processor is further configured to:
when an execution time of the event exceeds a scheduled execution time of the event, determine that the execution time of the event is abnormal; and
when an elapsed time between the events exceeds a scheduled elapsed time between the events, determine that the elapsed time between the events is abnormal.

8. The substrate processing congestion management apparatus of claim 6, wherein the at least one processor is further configured to:
derive contribution of each of the events by summing a difference between a start point of each of the events and a start point of the final suspected region and a different between a termination point of each of the events and a termination point of the final suspected region, an event with a smaller summed value referring to an event with a greater contribution to the final suspected region, and
set the event with the greatest contribution as the dominant event.

9. The substrate processing congestion management apparatus of claim 5, wherein the at least one processor is further configured to notify measures to adjust an event cycle based on content of the dominant event, process control parameters, or a process schedule.

10. The substrate processing congestion management apparatus of claim 1, wherein the at least one processor is further configured to:
receive data associated with the process sequence of the substrate processing apparatus; and
preprocess the received data.

11. A substrate processing congestion management apparatus comprising:
at least one processor configured to:
receive data associated with a process sequence of a substrate processing apparatus;
preprocess the received data;
divide the process sequence of the substrate processing apparatus into specific sections and determine whether congestion occurs in the specific sections;
set an initial suspected region corresponding to a section in which the congestion occurs, analyze outliers in events occurring in the initial suspected region, deduce a final suspected region while updating the initial suspected region based on an event in which an outlier is identified, and determine an event with a greatest contribution to the final suspected region as a congestion cause; and
notify the congestion cause and automatically control the substrate processing apparatus to reduce process congestion and improve substrate processing throughput, based on the determined congestion cause by performing at least one of:
adjusting gas flow parameters of at least one process chamber in the substrate processing apparatus;
modifying radio frequency (RF) power delivery timing in the at least one process chamber;
controlling pressure ramping rates between process steps performed by the substrate processing apparatus;
updating transfer robot scheduling between adjacent process chambers of the at least one process chamber; or
modifying maintenance timing of components in the at least one process chamber,
wherein a suspected region includes a section that contributes to the congestion cause, and
each of the events includes an action performed for processes by the substrate processing apparatus.

12. The substrate processing congestion management apparatus of claim 11, wherein the at least one processor is further configured to:
set, as a first monitoring section, a period from a point in time when a semiconductor substrate enters at least one process chamber of the substrate processing apparatus to a point in time when a process starts in the at least one process chamber;
set, as a second monitoring section, a period from a point in time when the process starts on the semiconductor substrate in the at least one process chamber to a point in time when the process ends;
set, as a third monitoring section, a period from a point in time when the process ends to a point in time when the semiconductor substrate is discharged from the at least one process chamber; and
set, as a fourth monitoring section, a period from a point in time when the semiconductor substrate is discharged from the at least one process chamber to a point in time when the semiconductor substrate enters a different process chamber.

13. The substrate processing congestion management apparatus of claim 12, wherein the at least one processor is further configured to:
set the initial suspected region corresponding to a monitoring section, in which the congestion occurs, from among the first monitoring section to the fourth monitoring section;
collect the events executed in the initial suspected region;
analyze whether there is an abnormality in execution times of the events or an elapsed time between the events;
set an execution time of an abnormal event or an elapsed time between abnormal events as suspected regions, update the initial suspected region with the suspected regions, and set a section, in which the suspected regions overlap, as a final suspected region; and
set, as a dominant event, the event with the greatest contribution to the final suspected region.

14. The substrate processing congestion management apparatus of claim 13, wherein the at least one processor is further configured to:
when the congestion occurs in the first monitoring section, set a period from a point in time, when the semiconductor substrate enters the at least one process chamber, to a point in time, when the semiconductor substrate is discharged from the at least one process chamber, as the initial suspected region;
when the congestion occurs in the second monitoring section, set a period from a point in time, when the semiconductor substrate enters the at least one process chamber, to a point in time, when the semiconductor substrate is discharged from the at least one process chamber, as the initial suspected region;
when the congestion occurs in the third monitoring section, set a period from a point in time, when the semiconductor substrate enters the at least one process chamber, to a point in time, when the semiconductor substrate enters the different process chamber, as the initial suspected region; and
when the congestion occurs in the fourth monitoring section, set a period from a point in time, when a process ends in the at least one process chamber, to a point in time, when a process ends in the different process chamber, as the initial suspected region.

15. The substrate processing congestion management apparatus of claim 14, wherein the at least one processor is further configured to:
when an execution time of the event exceeds a scheduled execution time of the event, determine that the execution time of the event is abnormal; and
when an elapsed time between the events exceeds a scheduled elapsed time between the events, determine that the elapsed time between the events is abnormal.

16. The substrate processing congestion management apparatus of claim 15, wherein the at least one processor is further configured to:
derive contribution of each of the events by summing a difference between a start point of each of the events and a start point of the final suspected region and a different between a termination point of each of the events and a termination point of the final suspected region, an event with a smaller summed value referring to an event with a greater contribution to the final suspected region, and
set the event with the greatest contribution as the dominant event.

17. A substrate processing system comprising:
a substrate processing apparatus comprising at least one process chamber configured to perform a process according to a process sequence;
a database configured to store data associated with the process sequence of the substrate processing apparatus; and
a substrate processing congestion management apparatus configured to analyze a congestion cause of the substrate processing apparatus based on the data associated with the process sequence,
wherein the substrate processing congestion management apparatus comprises at least one processor configured to:
receive the data associated with the process sequence from the database;
preprocess the received data;
divide the process sequence of the substrate processing apparatus into specific sections and determine whether congestion occurs in the specific sections;
set an initial suspected region corresponding to a section in which the congestion occurs, analyze outliers in events occurring in the initial suspected region, deduce a final suspected region while updating the initial suspected region based on an event in which an outlier is identified, and determine an event with a greatest contribution to the final suspected region as a congestion cause; and
notify the congestion cause,
a suspected region comprises a section that contributes to the congestion cause, and
each of the events includes an action performed for processes by the substrate processing apparatus.

18. The substrate processing system of claim 17, wherein the at least one processor is further configured to:
set, as a first monitoring section, a period from a point in time when a semiconductor substrate enters at least one process chamber of the substrate processing apparatus to a point in time when a process starts in the at least one process chamber;
set, as a second monitoring section, a period from a point in time when the process starts on the semiconductor substrate in the at least one process chamber to a point in time when the process ends;
set, as a third monitoring section, a period from a point in time when the process ends to a point in time when the semiconductor substrate is discharged from the at least one process chamber; and
set, as a fourth monitoring section, a period from a point in time when the semiconductor substrate is discharged from the at least one process chamber to a point in time when the semiconductor substrate enters a different process chamber.

19. The substrate processing system of claim 18, wherein the at least one processor is further configured to:
set the initial suspected region corresponding to a monitoring section, in which the congestion occurs, among the first monitoring section to the fourth monitoring section;
collect the events executed in the initial suspected region;
analyze whether the execution time of the event or an elapsed time between the events is abnormal;
set an execution time of an abnormal event or an elapsed time between abnormal events as suspected regions, update the initial suspected region with the suspected regions, and set a section, in which the suspected regions overlap, as a final suspected region; and
set, as a dominant event, the event with the greatest contribution to the final suspected region.

20. The substrate processing system of claim 19, wherein the at least one processor is further configured to:
when the congestion occurs in the first monitoring section, set a period from a point in time, when the semiconductor substrate enters the at least one process chamber, to a point in time, when the semiconductor substrate is discharged from the at least one process chamber, as the initial suspected region;
when the congestion occurs in the second monitoring section, set a period from a point in time, when the semiconductor substrate enters the at least one process chamber, to a point in time, when the semiconductor substrate is discharged from the at least one process chamber, as the initial suspected region;
when the congestion occurs in the third monitoring section, set a period from a point in time, when the semiconductor substrate enters the at least one process chamber, to a point in time, when the semiconductor substrate enters the different process chamber, as the initial suspected region; and
when the congestion occurs in the fourth monitoring section, set a period from a point in time, when a process ends in the at least one process chamber, to a point in time, when a process ends in the different process chamber, as the initial suspected region.
